(19) United States
(12) Patent Application Publication
(10) Pub. No.: US 2014/0266288 A1
(43) Pub. Date: Sep. 18, 2014

(54) Electrical Fault Detection

(71) Applicant: CONTROL TECHNIQUES LIMITED, Newtown (GB)

(72) Inventors: Paolo Trabacchin, Vicenza (IT); Colin Hargis, Oswestry (GB)

(73) Assignee: CONTROL TECHNIQUES LIMITED, Newtown (GB)

(21) Appl. No.: 14/206,944

(22) Filed: Mar. 12, 2014

(30) Foreign Application Priority Data
Mar. 15, 2013 (GB) 1304688.3

(51) Int. Cl. G01R 31/40

(52) U.S. Cl. CPC G01R 31/405
USPC 324/761.01

(57) ABSTRACT

An apparatus for detecting an arc on a circuit having a solar panel assembly is arranged to determine that an output of the solar panel assembly is below a threshold value and is therefore indicative of an arc on the circuit.

### CROSS-REFERENCE TO RELATED APPLICATION

This application claims the benefit and priority of Great Britain Patent Application No. 1304688.3 filed Mar. 15, 2013. The entire disclosure of the above application is incorporated herein by reference.

### FIELD

This disclosure relates to detecting a fault on a circuit. In particular, but without limitation, this disclosure relates to a method and apparatus for detecting an arc on a circuit having a solar panel assembly.

### BACKGROUND

Electrical energy may be distributed by an electrical distribution system in a number of different manners, exemplary manners including: by overhead electricity lines with exposed conductors, by insulated underground cable, or via solid conductors in an electrical substation. Electrical faults may occur in electrical distribution systems for a number of reasons, exemplary reasons including: water tracking across an insulating component; a breakdown of the insulating properties of an insulator, for example due to age or exposure of the insulator to the elements; and foreign bodies or conducting material falling onto bus bars. Electrical faults, such as electrical arcs, often generate significant amounts of heat and so can be dangerous and lead to fires and/or damage parts of the electrical distribution system.

Solar panels are power sources that produce DC output voltages when solar radiation is incident upon them. The voltage output by a solar panel is related to the level of radiation incident upon the solar panel, and even at relatively low levels of radiation, a solar panel can produce a considerable DC voltage (>100V DC). Accordingly, a fault in a system having one or more solar panels can result in the generation of considerable amounts of heat, or even fire, which can damage circuit components and endanger people who are in proximity to the fault.

### SUMMARY

Aspects and features of the present disclosure are set out in the appended claims.

An approach for detecting an arc on a circuit having a solar panel assembly is described. The approach comprises determining that a voltage produced by the solar panel assembly is below a threshold voltage and is therefore indicative of an arc on the circuit. The approach may further comprise determining the threshold voltage. The approach may further comprise receiving solar irradiance level information indicative of a solar irradiance level at the solar panel assembly and then determining the threshold voltage based upon the received solar irradiance level information.

As one possibility, the approach comprises receiving temperature information indicative of a temperature at the solar panel assembly and then determining the threshold voltage based upon the received temperature information. Advantageously, by employing temperature information, the threshold voltage may be greater than it would otherwise have been thereby increasing the approach's ability to discern when an arc has occurred.

As one possibility, the approach comprises receiving load information indicative of a load connected to the solar panel assembly and then determining the threshold voltage based upon the received load information. Advantageously, by employing load information, the threshold voltage may be greater than it would otherwise have been thereby increasing the approach's ability to discern when an arc has occurred.

According to one example of the present disclosure, there is provided a method for detecting a fault in a circuit having a solar panel assembly formed of one or more solar panels. Solar irradiance level information is received regarding a solar irradiance level at the solar panel assembly. The received information may be solar irradiance level information taken at the solar panel assembly or in the immediate vicinity thereof—for example, on the same site as the solar panel assembly. Information regarding a voltage produced by the solar panel assembly is received and a threshold voltage for the solar irradiance level indicated by the received solar irradiance level information is determined. The threshold voltage is compared to the voltage indicated by the received voltage information and, in the event that the voltage indicated by the received voltage information is beyond the determined threshold voltage, then a determination is made that the voltage indicated by the received voltage information is indicative of a fault. Once the likely presence of a fault has been determined, a signal indicating that determination may be sent thereby enabling an isolator, upon receipt of the signal, to isolate a part of the circuit so as to remove the fault.

There is also described herein a method and corresponding apparatus for detecting a fault on a circuit having a solar panel assembly, the method comprising measuring a solar irradiance level of the solar panel assembly, measuring a voltage produced by the solar panel assembly, comparing the measured voltage with a threshold voltage associated with the measured irradiance level and, responsive to the comparison, determining that the measured voltage is indicative of a fault.

Advantageously, as a solar plant may already have means for measuring solar irradiance levels installed in the vicinity of its solar panels (for example by way a meteorological measurement station), the method described herein may be employed without the need to install additional solar irradiance level measuring equipment. Furthermore, as solar panel assemblies which provide DC power via a DC voltage bus may already have means for measuring voltage on the DC voltage bus, the approach described herein may be implemented without the need for additional voltage measuring circuitry. Also, solar panel assemblies may have isolation devices associated therewith and so the approach described herein may be implemented without the need for additional isolation devices.

When a short circuit or a flash occurs between the positive and negative terminals of the solar panel or solar panel assembly, the voltage provided thereby may drop significantly and the current produced thereby increases. Accordingly, an arc that is present may continue to exist until the power source (the solar panel and/or the solar panel assembly) is isolated. By providing means for detecting the presence of a fault, action may be taken in order to prevent fires and/or damage caused by the fault.

### DRAWINGS

Examples of the present disclosure will now be explained with reference to the accompanying drawings in which:

FIG. 1 shows an exemplary diagram of an apparatus for detecting a fault on a circuit having a solar panel assembly;

FIG. 2 shows a flow chart illustrating a method for detecting a fault on a circuit having a solar panel assembly;

FIG. 3 shows a graph that illustrates an exemplary relationship between the solar irradiance level that a solar panel assembly is subjected to and a consequently produced output voltage;

FIG. 4 shows the exemplary relationship of FIG. 3 and additionally a curve representing threshold voltages for the solar irradiance levels of FIG. 3;

FIG. 5 shows a graph of an exemplary relationship between the solar irradiance level at a solar panel assembly and the voltage produced by the assembly when the assembly is at a variety of temperatures;

FIG. 6 shows the graph of FIG. 5 along with exemplary threshold voltages for use without knowledge of temperature or load information;

FIG. 7 shows the graph of FIG. 5 along with exemplary threshold voltages for use with knowledge of load information but without knowledge of temperature information;

FIG. 8 shows the graph of FIG. 5 along with exemplary threshold voltages for use with knowledge of temperature information but without knowledge of load information; and

FIG. 9 shows the graph of FIG. 5 along with exemplary threshold voltages for use with knowledge of temperature and load information.

### DETAILED DESCRIPTION

Some power sources, such as solar panels, can be severely current-limited. For some solar panels, once the solar panel has been exposed to a small amount of solar radiation, an increase in the level of radiation does not lead to a significant increase in the current produced by the solar panel. In circumstances where a fault occurs in a circuit supplied by a severely current-limited source, the inventor has appreciated that the current source will not be able to provide additional current and so the fault will not significantly increase the current drawn. Accordingly, an over-current approach to detecting faults will not work in such circumstances.

FIG. 1 shows a diagram of an exemplary apparatus for detecting a fault on a circuit 110 having a solar panel assembly 112 comprising one or more solar panels and being arranged to provide electrical energy to a load 114. An irradiance measurer 116 and a temperature measurer 117 are located in proximity to the solar panel assembly 112 so as to respectively be able to measure a solar irradiance level indicative of the amount of solar irradiation incident upon the solar panel assembly 112 and to measure a temperature indicative of the temperature at the solar panel assembly 112. A voltage measurer 118 is coupled to the circuit 110 so as to be able to measure a voltage produced by the solar panel assembly 112. In one example, the circuit 110 has a DC voltage bus that is supplied by the solar panel assembly and the voltage is measured at the DC voltage bus. FIG. 1 also shows a computer 120 having an input/output device 122, a processor 124 and a memory 126, the computer 120 being operable to load via the input/output device 122, and from a computer readable medium 123, computer readable programme instructions for storage in the memory 126 and which, when executed on the processor 124 cause the computer 120 to carry out all or part of any of the methods described herein. The input/output device 122 is coupled to the irradiance measurer 116 so as to be able to receive, from the irradiance measurer 116, solar irradiance level information that is indicative of a solar irradiance level at the solar panel assembly 112. The input/output device 122 is further operable to receive from the voltage measurer 118, voltage information that is indicative of the voltage produced by the solar panel assembly 112 at circuit point 113. The input/output device 122 is coupled to an isolator 128 which is arranged, upon receipt of a signal from the input/output device 122 to electrically isolate at least a portion of the circuit 110—in this example the isolator 128 is arranged to isolate the load 114 from the solar panel assembly 112. As one possibility, the isolator takes the form of a breaker device arranged to mechanically bring about a physical break in a circuit. The load 114 may optionally be connected to the input/output device 122 so as to be able to provide the computer 120 with load information.

A person skilled in the art will appreciate that although the above describes a solar panel assembly supplying a load and an isolator arranged to isolate the load from the solar panel assembly, as another or additional possibility, the isolator may be arranged to isolate one or more sub-portions of the solar panel assembly from one or more other portions of the solar panel assembly.

FIG. 2 shows a flow chart illustrating a method for detecting a fault on the circuit of FIG. 1. At step 202, solar irradiance level information that is indicative of a solar irradiance level at the solar panel assembly 112 is received at the computer 120 from the irradiance measurer 116. The solar irradiance level information may be in the form of a digital signal, for example a packetized data transmission and/or may be in the form of an analogue signal, for example a voltage provided by a photovoltaic cell.

At step 204, voltage information indicative of a voltage produced by the solar panel assembly 112 is received at the computer 120 from the voltage measurer 118. The voltage information may be in the form of a digital signal, for example a packetized data transmission and/or may be in the form of an analogue signal.

At step 206, a threshold voltage is determined for the solar irradiance level indicated by the received solar irradiance level information, the threshold voltage being indicative of the limit of expected and/or acceptable operating voltages for at least a part of the solar panel assembly when the assembly is subjected to a solar irradiance level equivalent to the solar irradiance level indicated by the received solar irradiance level information. Example approaches for determining the threshold voltage include: referencing a manufacturer's specification of the expected operating characteristics of at least part of the solar panel assembly 112, referencing empirically determined measurements of the performance of at least a part of the solar panel assembly 112, referencing calibration data for at least a part of the solar panel assembly 112, and/or calculating the threshold voltage from theory. Method step 206 may further involve accessing a lookup table, database, and/or stored equation parameters in order to determine the threshold voltage.

At step 208, the determined threshold voltage is compared with the voltage indicated by the received voltage information. Based upon the comparison, at step 210 a determination is made as to whether or not the voltage indicated by the received voltage information is indicative of a fault. In the example of FIG. 2, the determination criterion is whether or not the voltage indicated by the received voltage information is beyond the threshold voltage. If the voltage indicated by the received voltage information is beyond the threshold voltage, then the limits of expected and/or acceptable operating voltages have been traversed and a fault is indicated by the voltage indicated by the received voltage information.

As a further step in the method of FIG. 2, if it is determined at step 210 that a fault is indicated, the method may proceed to step 212. Alternatively, if it is determined at step 210 that a fault is not indicated, the method may return to step 202.

At step 212, a signal indicative of said fault is generated and transmitted by the computer 120 via the input/output device 122. The signal may be in the form of an alarm, for example an audible alarm, flashing light, or other visual indicator, and/or may be an electronic signal, such as a packetized or circuit switched communication and may contain information that can be used to log the determination of a fault—for example by recording the date and/or time of the fault/signal.

At step 214, the method may proceed to isolate at least a part of the circuit—for example the load 114. In particular, the isolator 128 is configured, upon receipt of the signal generated at step 212, to perform an isolation exercise in relation to the circuit 110—such as electrically isolating the load 114 from the solar panel assembly 112.

Although steps 202 and 204 are shown being performed sequentially in FIG. 2, the skilled person would understand that steps 202 and 204 may be performed sequentially in any order and/or concurrently.

Although in FIG. 2 step 212 is shown as occurring before step 214, a skilled person would understand that steps 212 and 214 may be transposed or combined; they would further understand that one or both of those steps may be omitted.

FIG. 3 depicts an illustrative graph of an exemplary relationship (plotted as curve 300) between the solar irradiance level at the solar panel assembly and the voltage produced by the assembly. The solar irradiance level at the solar panel assembly is shown on the x-axis and the voltage that is consequently produced by the solar panel assembly is shown on the y-axis. Accordingly, if a solar panel assembly having the plotted relationship between irradiance level and produced voltage were subjected to a solar irradiance level having a value ‘a’ then, during normal operation, one would expect a voltage of value ‘b’ to be produced by that solar panel assembly.

FIG. 4 shows the graph of FIG. 3 upon which a curve 410 is plotted showing a determined threshold voltage that varies with the irradiance level at the solar panel assembly. In addition, a voltage indicative of a fault is illustrated. In particular, for solar irradiance level ‘a’, a voltage lying between expected voltage ‘b’ and threshold voltage ‘c’ would be associated with normal/acceptable operation of the solar panel assembly. However, a voltage of ‘d’, which is below the lower range of acceptable voltages associated with solar irradiance level ‘a’, would indicate the presence of a fault.

Solar panel assemblies may be used to power one or more inverters or other loads that have multiple operating states. For example, an inverter may have an “on” state in which it is arranged to draw power from the solar panel assembly and an “off” state in which the inverter disconnects itself from the solar panel assembly. As inverters in an “on” state may feedback current to solar panel assemblies that they are connected to, in the event of an arc or other fault, the inverter may observe an change in current being fed back to the solar panel assembly and so may change into an “off” state. However, an inverter simply changing into its “off” state may not be sufficient to cause a fault to cease. Also, an inverter in an “on” state will load the solar panel assembly differently to an inverter in an “off” state. Further, changing the load that is connected to the solar panel assembly may consequently change the voltage produced by the solar panel assembly and so knowledge of the load that is connected to the solar panel assembly may be used to improve determination of the threshold voltage. As one possibility, a load containing an inverter is arranged to provide information about its state to the computer to enable that information to be taken into account when determining voltage thresholds.

The voltage produced by a solar panel assembly may be dependent upon the temperature at the solar panel array. FIG. 5 depicts a graph of an exemplary relationship between the solar irradiance level at the solar panel assembly and the voltage produced by the solar panel assembly when the solar panel assembly is at a variety of temperatures. The relationships are also shown for two exemplary scenarios: (i) when the load is connected to the circuit having the solar panel assembly (dashed curves); and (ii) when the load is not connected to the circuit having the solar panel assembly (solid curves). The solar irradiance level at the solar panel assembly is shown on the x-axis and the voltage that is consequently produced by the solar panel assembly is shown on the y-axis.

Curve 510 depicts the relationship between the voltage produced by the solar panel assembly and the solar irradiance level at the solar panel assembly when the solar panel assembly is at a temperature of −25° C. and the load is disconnected. That is, curve 510 shows the relationship between the expected open circuit voltage and the irradiance when the solar panel is at −25° C. Curve 550 shows the relationship between the voltage produced by the solar panel assembly and the solar irradiance level at the solar panel assembly when the solar panel assembly is at a temperature of −25° C. and the load is connected. Curve 520 shows the relationship between the voltage and the irradiance level when the solar panel assembly is at 0° C. and the load is not connected; curve 560 shows the relationship between the voltage produced by the solar panel assembly and the irradiance level when the solar panel assembly is at 0° C. and the load is connected. Curve 530 shows the relationship between the voltage and the irradiance level when the solar panel assembly is at 25° C. and the load is not connected; curve 570 shows the relationship between the voltage produced by the solar panel assembly and the irradiance level when the solar panel assembly is at 25° C. and the load is connected. Curve 540 shows the relationship between the voltage and the irradiance level when the solar panel assembly is at 50° C. and the load is not connected; curve 560 shows the relationship between the voltage produced by the solar panel assembly and the irradiance level when the solar panel assembly is at 50° C. and the load is connected.

If, for example, a solar panel assembly having the characteristics of FIG. 5 was at a temperature of −25° C. and was connected to the load and subjected to a solar irradiance level of 300 W/m² then, during normal operation, one would expect a voltage of approximately 750V to be produced. The expected open circuit voltage of a solar panel assembly under such circumstances would be approximately 900V.

FIG. 6 shows the graph of FIG. 5 and in addition depicts a “trip area” 600, bounded by a threshold voltage 610. If, for a given circumstance, the intersection point on the graph of FIG. 6 of the irradiance level and the voltage produced by the solar panel assembly was found to lie within the trip area 600, then the arc detection apparatus would determine that the voltage produced by the solar panel assembly is indicative of an arc. In the example of FIG. 6, the threshold voltage 610 does not vary continuously and is instead constant for some values of the solar irradiance level at the solar panel assembly. In particular, the threshold voltage 610 is zero for low values of irradiance, but non-zero for irradiance levels above an irradiance threshold 640. If the irradiance level at the solar panel assembly is below the irradiance threshold 640 then the arc detection device does not determine that any received voltage information is indicative of an arc.

To avoid the isolator being activated spuriously, the trip area 600 of FIG. 6 is defined so as to lie below the curves 510-580 of FIG. 6. This makes a device configured so as to operate in accordance with the trip area 600 of FIG. 6 insensitive to both the temperature of the solar panel array and to the presence or absence of any load.

As there may be some deviation from the theoretical shape of the curves 510-580 of FIG. 6 and those encountered in practice—for example due to measurement errors, the threshold voltage is chosen to be somewhat below the minimum expected voltage for the range of expected operating temperatures and loads. The difference between that minimum expected voltage and the threshold voltage is indicated in FIG. 6 by reference sign 620. FIG. 6 also indicates, by reference sign 630, the maximum range of voltages over which a voltage produced by the solar panel assembly may differ from the uppermost of the curves 510-580 without indicating the presence of a fault.

FIG. 7 shows the graph of FIG. 5 and in addition depicts a trip area 700 with a threshold voltage 710 and a threshold irradiance level 740. In this case, the apparatus has received load information indicating that the load is not connected to the circuit having the solar panel assembly but has not received temperature information indicative of a temperature at the solar panel assembly. The threshold voltage 710 is determined to be at a value sufficiently low as to be insensitive to the temperature at the solar panel array, and yet sufficiently high as to take account of the information received that indicates that the load is not connected. The difference between the minimum expected voltage and the threshold voltage is indicated in FIG. 7 by reference sign 720 and the maximum range of voltages over which a voltage produced by the solar panel assembly may differ from the uppermost of the curves 510-580 without indicating the presence of a fault is indicated in FIG. 7 by reference sign 730. As can be seen, by taking account of the information received that indicates that the load is not connected, the maximum range of voltages over which a voltage produced by the solar panel assembly may differ from the uppermost of the curves 510-580 without indicating the presence of a fault 730 is reduced when compared to that of FIG. 6.

FIG. 8 shows the graph of FIG. 5 and in addition depicts a trip area 800 with a threshold voltage 810 and a threshold irradiance level 840. In this case, the apparatus has received temperature information indicating that the temperature at the solar panel assembly is −25° C. but has not received load information indicating whether the load is or is not connected to the circuit having the solar panel assembly. The threshold voltage 810 is determined to be at a value sufficiently low as to be insensitive to whether the load is or is not connected to the circuit having the solar panel assembly, and yet sufficiently high as to take account of the received temperature information. The difference between the minimum expected voltage and the threshold voltage is indicated in FIG. 8 by reference sign 820 and the maximum range of voltages over which a voltage produced by the solar panel assembly may differ from the uppermost of the curves 510-580 without indicating the presence of a fault is indicated in FIG. 8 by reference sign 830. As can be seen, by taking account of the received temperature information, the maximum range of voltages over which a voltage produced by the solar panel assembly may differ from the uppermost of the curves 510-580 without indicating the presence of a fault 830 is reduced when compared to that of FIG. 6.

The apparatus may receive both temperature information indicative of the temperature at the solar panel assembly and load information indicating that the load is not connected. FIG. 9 shows the graph of FIG. 5 and in addition depicts a trip area 900 with a threshold voltage 910 and a threshold irradiance level 940. In this case, the apparatus has received temperature information indicating that the temperature at the solar panel assembly is −25° C. and has also received load information indicating that the load is not connected to the circuit having the solar panel assembly. The threshold voltage 910 is determined to be sufficiently high so as to take into account the received temperature information and the received load information. The difference between the minimum expected voltage and the threshold voltage is indicated in FIG. 9 by reference sign 920 and the maximum range of voltages over which a voltage produced by the solar panel assembly may differ from the uppermost of the curves 510-580 without indicating the presence of a fault is indicated in FIG. 9 by reference sign 930. As can be seen, by taking account of both the received temperature information and the received load information, the maximum range of voltages over which a voltage produced by the solar panel assembly may differ from the uppermost of the curves 510-580 without indicating the presence of a fault 930 is reduced when compared to that of FIGS. 6, 7, and 8.

A person skilled in the art will appreciate that, although FIG. 1 shows the isolator 128 being arranged to isolate the load 114 of the circuit 110, the isolator could instead be configured to isolate different portions of the circuit. For example, the isolator could be configured to isolate only a part of the load 114 and/or to isolate a portion of the solar panel assembly. A person skilled in the art will further understand that, although in the above the isolator is described as comprising a mechanical breaker for breaking a circuit, other devices having the same or equivalent functionality could equally be employed.

As one possibility, an apparatus comprising: a solar irradiance detector, a solar panel assembly, and a voltage measurer for measuring a voltage provided by the solar panel assembly, is arranged to determine whether the measured voltage is indicative of a fault in the solar panel assembly.

A person skilled in the art will understand that the use herein of the term “isolation” and the verb “to isolate” relate to the electrical isolation of a device/component and that accordingly, in order for such a device/component to be isolated, an action needs to be taken to prevent current flowing between that device/component and another device/component of the circuit. Accordingly, two devices/components may share a common connection point, for example earth/ground, yet be isolated within the context of this disclosure if current is not able to flow between those devices/components.

A person skilled in the art will appreciate that the threshold voltage used to determine that a voltage produced by the solar panel assembly is indicative of a fault may vary continuously or discontinuously with the irradiance level at the solar panel assembly.

A person skilled in the art will appreciate that the above description in relation to the voltage indicated by the received voltage information being beyond the threshold voltage could mean that the voltage indicated by the received voltage information is below the threshold voltage. As one possibility the method and apparatus described herein determine a threshold voltage that delineates a range of acceptable values for the voltage indicated by the received voltage information given the received solar irradiance level information. The measured voltage is then compared to the threshold voltage and a fault is determined if the measured voltage lies below the threshold voltage.

A person skilled in the art will understand that the term “solar irradiance level” relates to a measure of the power imparted to an object per unit area as a consequence of solar radiation being incident upon that object. Different units may be employed when measuring a solar irradiance level and exemplary units include watts per square metre. A person skilled in the art would understand that the use of different units for the measurement of the power imparted to an object per unit area as a consequence of solar radiation being incident upon that object cannot change the nature of the underlying quantity that is being measured. Indeed, in some implementations, for example those that produce an analogue electrical signal indicative of the solar irradiance level, the quantity measured may have a completely different unit (i.e. volts) without departing from the inherent information conveyed by the measured quantity about the solar irradiance level. As one possibility the solar irradiance level may be evaluated as a binary quantity with a “1” indicating that irradiation is occurring and a “0” indicating that irradiation is not occurring (or vice versa). Accordingly, solar irradiance level information indicative of the solar irradiance level may also be a binary quantity. Also, a person skilled in the art will recognise that solar radiation levels may be measured by a number of different means, for example: pyranometers, pyrheliometers, and/or photovoltaic cells.

There is described herein an apparatus for detecting an arc on a circuit having a solar panel assembly. The apparatus being arranged to determine that an output of the solar panel assembly is below a threshold value and is therefore indicative of an arc on the circuit.

A person skilled in the art will appreciate that, whilst load information may indicate whether or not a load is connected to the solar panel assembly, additionally or alternatively, load information may indicate the magnitude of a load connected to the solar panel assembly, for example by indicating a load impedance.

A person skilled in the art will appreciate that the terms “irradiance”, “irradiance level” and “irradiation level” may be interchanged throughout this disclosure.

A computer readable medium may carry computer readable instructions arranged, upon execution by a processor, to cause the processor to carry out any or all of the methods described herein.

1. A method for detecting an arc on a circuit having a solar panel assembly, the method comprising determining that a voltage produced by the solar panel assembly is below a threshold voltage and is therefore indicative of an arc on the circuit.

2. The method of claim 1, comprising determining the threshold voltage.

3. The method of claim 2, comprising receiving solar irradiance level information indicative of a solar irradiance level at the solar panel assembly, wherein the threshold voltage is determined based upon the received solar irradiance level information.

4. The method of claim 3, wherein the threshold voltage is a lower limit of voltages associated with normal operation of the circuit when the solar panel assembly is subjected to the solar irradiance level indicated by the received solar irradiance level information.

5. The method of claim 1, comprising measuring a solar irradiance level indicative of the solar irradiance level at the solar panel assembly, optionally wherein the measuring a solar irradiance level comprises measuring the solar irradiance level at the solar panel assembly.

6. The method of claim 2, comprising receiving temperature information indicative of a temperature at the solar panel assembly, wherein the threshold voltage is determined based upon the received temperature information.

7. The method of claim 2, comprising receiving load information indicative of a load connected to the solar panel assembly, wherein the threshold voltage is determined based upon the received load information.

8. The method of claim 1, comprising responsive to the determining that the voltage produced by the solar panel assembly is indicative of an arc on the circuit, sending a signal indicative of the arc.

9. The method of claim 1, comprising responsive to the determining that the voltage produced by the solar panel assembly is indicative of an arc on the circuit, electrically isolating at least a part of the solar panel assembly.

10. The method of claim 1, comprising measuring the voltage produced by the solar panel assembly, optionally wherein the measuring a voltage comprises measuring a DC bus voltage in the circuit.

11. A computer readable medium carrying computer readable instructions arranged for execution by a processor so as to cause the processor to carry out the method of claim 1.

12. An apparatus for detecting an arc on a circuit having a solar panel assembly, the apparatus being arranged to determine that a voltage produced by the solar panel assembly is below a threshold voltage and is therefore indicative of an arc on the circuit.

13. The apparatus of claim 12, wherein the apparatus is further arranged to determine the threshold voltage.

14. The apparatus of claim 13, the apparatus being arranged to receive solar irradiance level information indicative of a solar irradiance level at the solar panel assembly, and to determine the threshold voltage based upon the received solar irradiance level information, optionally wherein the threshold voltage is a lower limit of voltages associated with normal operation of the circuit when the solar panel assembly is subjected to the solar irradiance level indicated by the received solar irradiance level information.

15. The apparatus of claim 12, the apparatus being further arranged to measure a solar irradiance level indicative of the solar irradiance level at the solar panel assembly, optionally wherein the apparatus is arranged to measure the solar irradiance level at the solar panel assembly.

16. The apparatus of claim 13, the apparatus being arranged to receive temperature information indicative of a temperature at the solar panel assembly and to determine the threshold voltage based upon the received temperature information.

17. The apparatus of claim 13, the apparatus being arranged to receive load information indicative of a load connected to the solar panel assembly and to determine the threshold voltage based upon the received load information.

18. The apparatus of claim 12, the apparatus being arranged to send a signal indicative of the arc responsive to determining that the voltage produced by the solar panel assembly is indicative of an arc on the circuit.

19. The apparatus of claim 12, the apparatus being further arranged to electrically isolate at least a part of the solar panel assembly responsive to determining that the voltage produced by the solar panel assembly is indicative of an arc on the circuit.

20. The apparatus of claim 12, wherein the apparatus is arranged to measure the voltage produced by the solar panel assembly, optionally wherein the apparatus is arranged to measure a DC bus voltage produced by the solar panel assembly.
